(19) United States
(12) Patent Application Publication
(10) Pub. No.: US 2023/0084375 A1
(43) Pub. Date: Mar. 16, 2023

(54) SELECTIVE PROTECTION OF INTEGRATED CIRCUIT CHIP SURFACE REGIONS FROM UNDERFILL CONTACT

(71) Applicant: Intel Corporation, Santa Clara, CA (US)

(72) Inventors: Priyanka Dobriyal, Milpitas, CA (US); Ankur Agrawal, Chandler, AZ (US); Anna M. Prakash, Chandler, AZ (US); Ann J. Xu, Chandler, AZ (US); Jimin Yao, Chandler, AZ (US); Raiyomand F. Aspandiar, Portland, OR (US); Lesley A. Polka Wood, Chandler, AZ (US); Abigail G. Agwai, Chandler, AZ (US); Kayleen L. E. Helms, Chandler, AZ (US)

(73) Assignee: Intel Corporation, Santa Clara, CA (US)

(21) Appl. No.: 17/475,123

(22) Filed: Sep. 14, 2021

(51) Int. Cl. H01S 5/0237; H01S 5/0234

(52) U.S. Cl. CPC H01S 5/0237; H01S 5/0234

(57) ABSTRACT

An apparatus comprising an integrated circuit chip comprising a first surface region and a second surface region adjacent to the first surface region; a substrate coupled to the integrated circuit chip through a plurality of connections comprising solder; and underfill between the substrate and the integrated circuit chip, wherein the underfill contacts the second surface region, but does not contact the first surface region.

### BACKGROUND

Flip chip packaging refers to a method for interconnecting an integrated circuit chip to an external circuit (e.g., a printed circuit board) using solder joints (e.g., bumps) deposited onto the external circuit and/or the pads of the chip. In some implementations, the solder joints may be deposited on the pads of the chip on the top side of the wafer during manufacturing of the wafer. Alternatively or additionally, the solder joints may be deposited onto the external circuit (e.g., onto pads of the external circuit). The chip is then flipped over and the pads of the chip are aligned with pads of the external circuit. The solder is re-melted (e.g., using thermocompression bonding or a reflow solder process) to form connections between the chip and the external circuit.

An underfill material is then applied to the space between the chip and the external circuit in order to improve the structural integrity of the connection. The underfill may include, e.g., an electrically-insulating material such as a resin or other multi-composite material, which could have multiple different levels of phases of particulates. After application, the underfill is hardened (relative to the state of the underfill during the application process) via a cure process. The underfill, in various situations, may provide a more robust mechanical connection, may remove stress on the solder joints (to reduce the likelihood of connection fracture), and/or may provide a heat bridge.

### BRIEF DESCRIPTION OF THE DRAWINGS

FIG. 1 depicts a transmitter optical sub-assembly comprising a plurality of laser regions, in accordance with any of the embodiments disclosed herein.

FIGS. 2A-2C depict hydrophobic cylinders and trenches to protect a surface of a laser region from underfill, in accordance with any of the embodiments disclosed herein.

FIGS. 3A-3B depict a hydrophobic film to protect a surface of a laser region from underfill, in accordance with any of the embodiments disclosed herein.

FIGS. 4A-4D depict sacrificial films and resulting air gaps to protect a surface of a laser region from underfill, in accordance with any of the embodiments disclosed herein.

FIGS. 5A-5B depict a silicon wafer piece to protect a surface of a laser region from underfill, in accordance with any of the embodiments disclosed herein.

FIG. 6A-6E depict Benzo Cyclo Butane reinforced with nickel mesh and a corresponding flow to protect a surface of a laser region from underfill, in accordance with any of the embodiments disclosed herein.

FIGS. 7A-7C depicts a dielectric barrier to protect a surface of a laser region from underfill and a flow to applying the structure, in accordance with any of the embodiments disclosed herein.

FIGS. 8A-8B depict polymers to protect a surface of a laser region from underfill, in accordance with any of the embodiments disclosed herein.

FIGS. 9A-9D depict release tape and an associated flow to protect a surface of a laser region from underfill, in accordance with any of the embodiments disclosed herein.

FIG. 10 depicts a hydrophobic material, in accordance with any of the embodiments disclosed herein.

FIG. 11 depicts a top view of a wafer and dies that may be included in a microelectronic assembly, in accordance with any of the embodiments disclosed herein.

FIG. 12 depicts a cross-sectional side view of an integrated circuit device that may be included in a microelectronic assembly, in accordance with any of the embodiments disclosed herein.

FIG. 13 depicts a cross-sectional side view of an integrated circuit device assembly that may include a microelectronic assembly, in accordance with any of the embodiments disclosed herein.

FIG. 14 depicts a block diagram of an example electrical device that may include a microelectronic assembly, in accordance with any of the embodiments disclosed herein.

### DETAILED DESCRIPTION

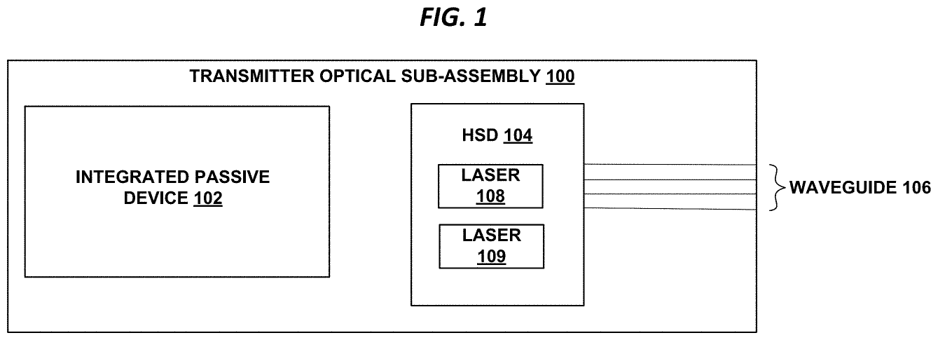

FIG. 1 depicts a transmitter optical sub-assembly (TOSA) 100 comprising an integrated passive device 102 and a heat sink device (HSD) 104. The HSD 104 comprises laser regions 108 and 109. The HSD 104 may help disperse heat generated by the lasers. A laser may include, e.g., a laser diode device. The TOSA 100 also includes waveguide 106. In various embodiments, the TOSA 100 may be a component of a transceiver that provides conversion between electrical signals and optical signals. The TOSA 100 may be embodied on an integrated circuit chip having a plurality of pads for connection to an external circuit (e.g., a printed circuit board (PCB) or other substrate).

Silicon photonics is an emerging technology in which performance and reliability are at a premium. In various scenarios, flip chip packaging techniques provide the ability to provide advanced packaging solutions with improved characteristics relative to other packaging techniques (e.g., wire bonding) which may result, e.g., in higher impedance connections. However, underfill that contacts the surface of the laser region 108 or 109 may transfer stress to the quantum well layer due to the strong bond that the underfill forms to the surface of a laser region, affecting the performance and reliability of the laser and may ultimately cause failure.

In various embodiments of the present disclosure, avoiding underfill contact with photonic integrated circuits (ICs) in the laser region may enable flip chip (FC) assembly of photonic IC chips (e.g., on high performance organic substrates for co-packaged optics (CPO) in datacenters as well as other adjacencies such as FC lidar, among other applications), by reducing or eliminating stress effects that would cause laser performance and reliability failures. Various embodiments may also conserve space on a substrate (e.g., PCB) relative to other packaging approaches, which may ease constraints as pluggable transceivers are scaled for higher bandwidth applications (800G, 1.6T, and beyond).

Although the embodiments disclosed herein focus on avoiding underfill contact with one or more surfaces of laser regions 108, 109 of a photonic IC chip, other embodiments include use of the techniques and structures in other applications in order to prevent underflow from contacting any sensitive surface region of an IC chip. For example, the techniques may be used with other IC chips (e.g., opto-electronic devices) with regions sensitive to underfill, such as waveguide regions, wire bond pads, plating through board vias, sensors, and microelectromechanical systems (MEMS) devices. Thus, any reference below to a laser region (e.g., 206) may in various embodiments refer to any suitable region that may be harmed via contact with the underfill).

Underfill contact with a surface of a laser region 108, 109 (or other surface regions that may be harmed via contact with the underfill) may be avoided by various techniques and structures, including protective coverings (e.g., a barrier comprising a hydrophobic film or silicon, a sacrificial film to operate as a barrier in order to create an air gap, or a thermal/ultraviolet (UV) release tape), protective materials proximate to the first surface region (e.g., the aforementioned protective coverings, vertical hydrophobic cylinders, mesh structures, other underfill flow retarding barrier geometries), or trenches, among techniques and structures.

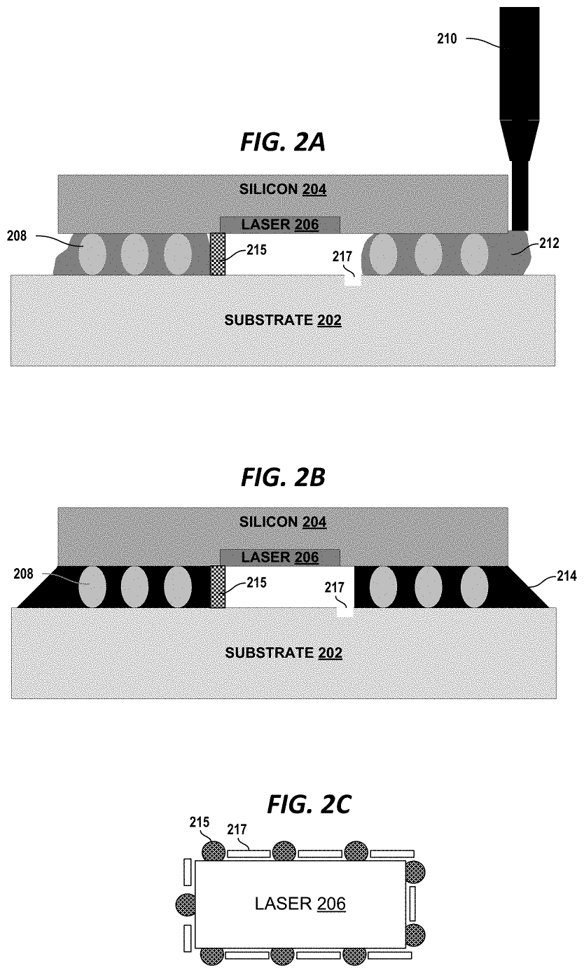

FIGS. 2A-2C depict hydrophobic cylinders 215 and trenches 217 to protect a laser region 206 from underfill 212, in accordance with any of the embodiments disclosed herein. The laser region 206 is formed on a chip comprising silicon 204. The chip may be any suitable IC chip. When the chip is formed, the laser region 206 may be a surface on the top of the chip and then the chip is flipped upside down and connected to the substrate 202. In some embodiments, laser region 206 may correspond to surface of a laser region 108 or 109.

In various embodiments, underfill 212 is placed between the chip and the substrate 202 in selective regions. For example, the underfill 212 may be in contact with one or more surface regions of the chip, but not in contact with one or more other surface regions of the chip, where a surface region may refer to a portion of the bottom of the chip in the embodiment depicted (which may be the top of the chip during manufacturing before the chip is flipped over). For example, the underfill 212 does not contact a first surface region of the chip that includes the entire surface of the laser region 206, a portion (e.g., a majority) of the laser region 206, or the entire surface of the laser region 206 and some of the surface area adjacent to the laser region 206. However, the underfill 212 does contact one or more surface regions of the chip that are adjacent (e.g., immediately adjacent) to the first surface region (e.g., the surface region(s) surrounding the first surface region).

Substrate 202 (e.g., of external circuitry) comprises solder joints 208 (e.g., solder balls or other geometries) for attachment to the chip (e.g., via pads of the chip or extensions thereof, such as copper pillars). In alternative embodiments, solder joints 208 may be formed on the IC chip instead of or in addition to the substrate 202. Before the chip is attached to the substrate 202, hydrophobic cylinders 215 (or other hydrophobic structures having other suitable geometries) and/or trenches 217 may be formed on the substrate 202. In various embodiments hydrophobic cylinders 215 and/or trenches 217 may be formed on the substrate 202 prior to or after the formation of the solder joints 208.

When the integrated circuit chip is connected to the substrate 202, the integrated circuit chip may be aligned with the substrate. For example, the pads of the silicon chip are placed over the solder joints 208 and the solder is melted and then allowed to harden to couple pads of the substrate 202 to pads of the IC chip. An underfill dispenser 210 then applies underfill 212 to the space between the silicon 204 and the substrate 202 (with the underfill contacting surface regions of the substrate 202 and the IC chip). The underfill may flow to open areas, including spaces around the solder joints 208. The underfill 212 may also contact the solder joints 208. After the underfill 212 has been dispensed, it undergoes a curing process. The cured underfill 214 is depicted in FIG. 2B.

As shown in FIG. 2C (which is a top view of the laser region 206, hydrophobic cylinders 215, and trenches 217), the hydrophobic cylinders 215 and trenches 217 are formed on the substrate at or near the perimeter of the area of the substrate that sits below the laser region 206. The hydrophobic cylinders 215 repel the flow of the underfill 212 to prevent contact between the surface of the laser region 206 with the underfill 212. The trenches 217 may also be placed at or near the perimeter of the area of the substrate that sits below the laser region to act as micro dams to accept excess underfill 212 that flows towards the laser region (in the embodiments depicted in FIGS. 2A and 2B, the underfill has not reached the trench 217, but in other embodiments the underfill may at least partially fill one or more of the trenches 217).

In the embodiment depicted, the hydrophobic cylinders 215 and trenches 217 surround the entire perimeter of the laser region 206. In other embodiments (e.g., dependent on the layout of the laser region 206 and the underfill application process), the hydrophobic cylinders 215 and trenches 217 may only surround a portion of the perimeter.

In the embodiment depicted, the hydrophobic cylinders 215 and trenches 217 are placed in an alternating pattern (e.g., a trench 217 is placed between two hydrophobic cylinders 215 and vice versa). In other embodiments, any suitable pattern may be used (e.g., two or more hydrophobic cylinders 215 for every trench 217, two or more trenches 217 for every hydrophobic cylinder 215, etc.).

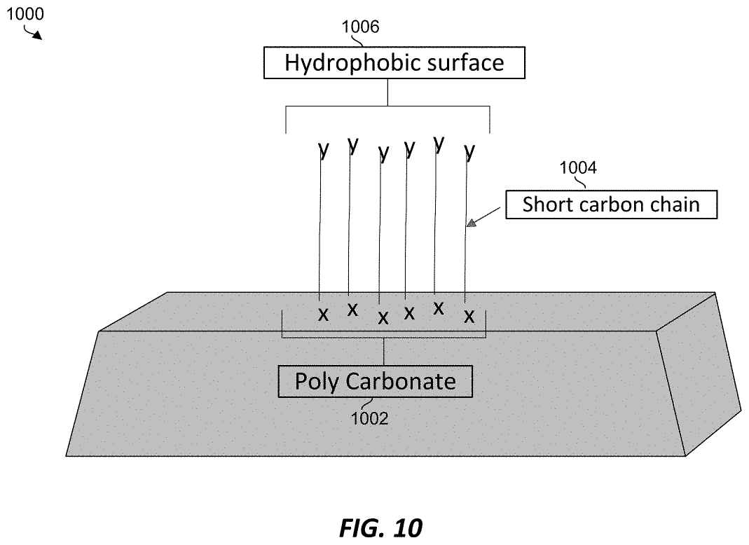

In various embodiments, instead of hydrophobic cylinders 215, any other geometry may be used (e.g., pillars, blocks, etc). Similarly, the trenches 217 may have any suitable shape or depth. The trenches 217 may be formed in any suitable manner, such as etching or laser ablation. Formation techniques for the hydrophobic cylinders 215 will be discussed below (e.g., in connection with FIG. 10).

Some embodiments may include hydrophobic cylinders 215 (or other geometries), but not trenches 217. Other embodiments may include trenches 217, but not hydrophobic cylinders 215.

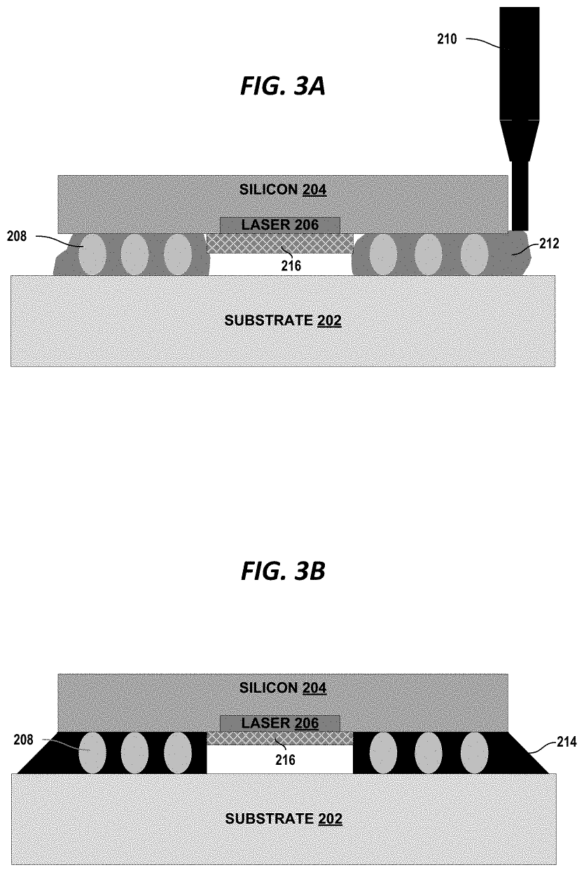

FIGS. 3A-3B depict a hydrophobic film 216 to protect a surface of a laser region 206 from underfill 212, in accordance with any of the embodiments disclosed herein. The hydrophobic film 216 may be formed on the surface of the laser region 206 as part of the chip manufacturing process (e.g., before the wafer is sliced). The hydrophobic film 216 may cover at least a portion of the surface of the laser region 206 and in some embodiments may cover the entire surface and some of the surrounding surface area of silicon 204. In some embodiments (e.g., as shown in FIG. 3A), the thickness of the hydrophobic film 216 is smaller than the thickness of the solder joints 208 (and/or the gap between the silicon 204 and the substrate 202 when the silicon 204 and the substrate 202 are aligned during the connection process) such that the bottom of the hydrophobic film 216 does not contact the substrate 202 when the chip is flipped and placed on the substrate prior to the melting of the solder joints 208. In another embodiment, the hydrophobic film 216 may have a thickness substantially equal to the thickness of the solder joints 208 (and/or the gap between the silicon 204 and the substrate 202), but is not so thick that it interferes with the process of connecting the chip and the substrate through the melting of the solder. The hydrophobic film 216 repels the underfill 212 and prevents the underfill 212 from contacting the surface of the laser region 206. As depicted in FIG. 3B, in some embodiments, the hydrophobic film 216 may undergo physical changes and the thickness may be reduced during the curing process for the underfill 214.

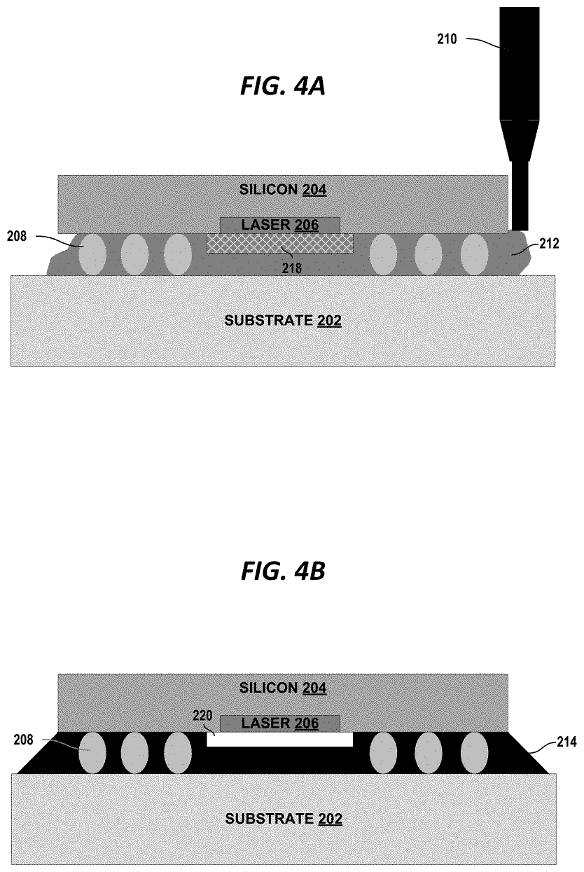

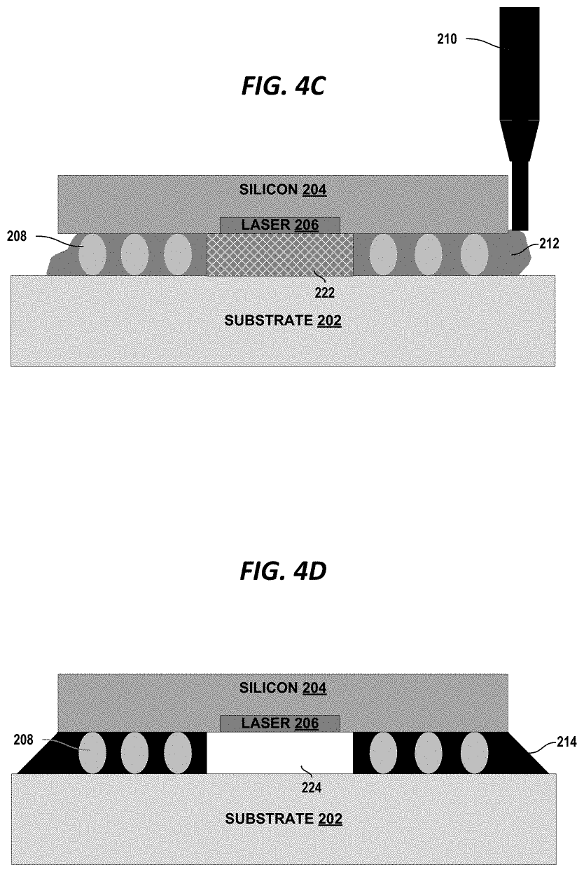

FIGS. 4A-4D depict sacrificial films 218 and 222 and resulting air gaps 220 and 224 to protect a surface of a laser region 206 from underfill 212, in accordance with any of the embodiments disclosed herein. A sacrificial film 218 or 222 may be formed on the surface of the laser region 206 as part of the chip manufacturing process (e.g., before the wafer is sliced). The sacrificial film 218 or 222 may cover at least a portion of the surface of the laser region 206 and in some embodiments may cover the entire surface and some of the surrounding surface area of silicon 204.

In the embodiment of FIG. 4A, the thickness of the sacrificial film 218 is smaller than the thickness of the solder joints 208 (and/or the gap between the silicon 204 and the substrate 202) such that the bottom of the sacrificial film 218 does not contact the substrate 202 when the chip is flipped and placed on the substrate prior to the melting of the solder joints 208. In some embodiments, the sacrificial film 218 is relatively thin when compared with the thickness of the solder joints 208. For example, the sacrificial film 218 may be less than half of the thickness of the solder joints 208. In other embodiments (e.g., as shown in FIG. 4C), the sacrificial film 222 has a thickness that is substantially equal to the thickness of the solder joints 208.

The sacrificial films 218 and 222 prevent the underfill 212 from contacting the laser region 206 during the dispensing of the underfill 212. During the curing of the underfill, the sacrificial film 218 decomposes, forming an air gap 220 (e.g., a micro level air gap). Similarly, the sacrificial film 222 decomposes during underfill cure, forming a larger air gap 224. An air gap 220 or 224 may form a keep-out zone between the cured underfill 214 and the surface of the laser region 206.

Any suitable material may be used as the sacrificial film 218 or 222. For example, the sacrificial film 218 or 222 may include a poly(alkylene carbonate) sacrificial coating that decomposes during reflow of the solder joints 208 or can be burned off after reflow. In various embodiments, the sacrificial film 218 or 222 may survive (in whole or in part) reflow temperatures (e.g., 230-265° C.). In another example, the sacrificial film may comprise a polymer such as PDM-5034 manufactured by Promerus. In other examples, sacrificial film 218 or 222 may comprise an epoxy based polymer or rosin (e.g., with a high glass transition temperature and cross linking), which in some embodiments may dissolve in the underfill. In some embodiments, the air gap underneath the laser region 206 may be generated before the underfill cure (e.g., by decomposition of the sacrificial film).

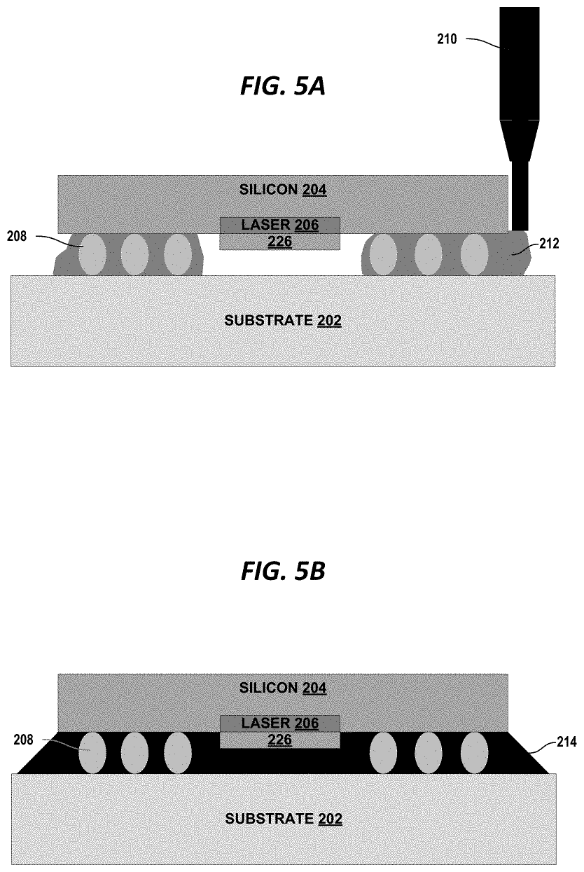

FIGS. 5A-5B depict a silicon wafer piece 226 to protect a laser region 206 from underfill, in accordance with any of the embodiments disclosed herein. The silicon wafer piece 226 may cover at least a portion of the surface of the laser region 206 and in some embodiments may cover the entire surface and some of the surrounding surface area of silicon 204. In some embodiments, the silicon wafer piece does not include any copper (Cu) (or at least not an appreciable amount of Cu) as the Cu may have a deleterious effect on the laser region 206. In various embodiments, the silicon wafer piece may be doped using other elements.

In some embodiments (e.g., as shown in FIG. 5A), the thickness of the silicon wafer piece 226 is smaller than the thickness of the solder joints 208 such that the bottom of the silicon wafer piece 226 does not contact the substrate 202 when the chip is flipped and placed on the substrate prior to the remelting of the solder joints 208. Thus, the underfill may flow around and under the silicon wafer piece 226 as shown by the cured underfill 214 in FIG. 5B. In another embodiment, the silicon wafer piece 226 could have another suitable thickness, such as a thickness substantially equal to the thickness of the solder joints 208 (and/or the gap between the silicon 204 and the substrate 202), but is not so thick that it interferes with the process of connecting the chip and the substrate through the remelting of the solder. The silicon wafer piece 226 prevents the underfill 212 from contacting the surface of the laser region 206.

In some embodiments, the silicon wafer piece 226 may be temporarily attached to the laser region 206, e.g., by double sided tape or other temporary adhesion that contacts the surface of the laser region 206 and the silicon wafer piece 226. In various embodiments, the silicon wafer piece 226 may be held against the surface of the laser region 206 during the underfill application process by thermal grease or other material that will not significantly compact during the underfill curing process. After the underfill 212 is dispersed, the silicon wafer piece 226 may detach from the laser region 206. In various embodiments, the coefficient of thermal expansion (CTE) of the surface of the laser region 206 (which may comprise Indium Phosphide (InP) in some embodiments) may be substantially similar to the CTE of the silicon wafer piece 226. For example, the CTE of InP may be 4.6×10-6/0 C while the CTE of Si may be 2.6×10-6/0 C. Maintaining similar CTEs in these components may avoid a high amount of shear stress generated during temperature excursion from the zero stress state which may lead to cracks or de-adhesion leading to interfacial separation between the laser region 206 and the silicon wafer piece 226 (which may occur if a large CTE mismatch were present).

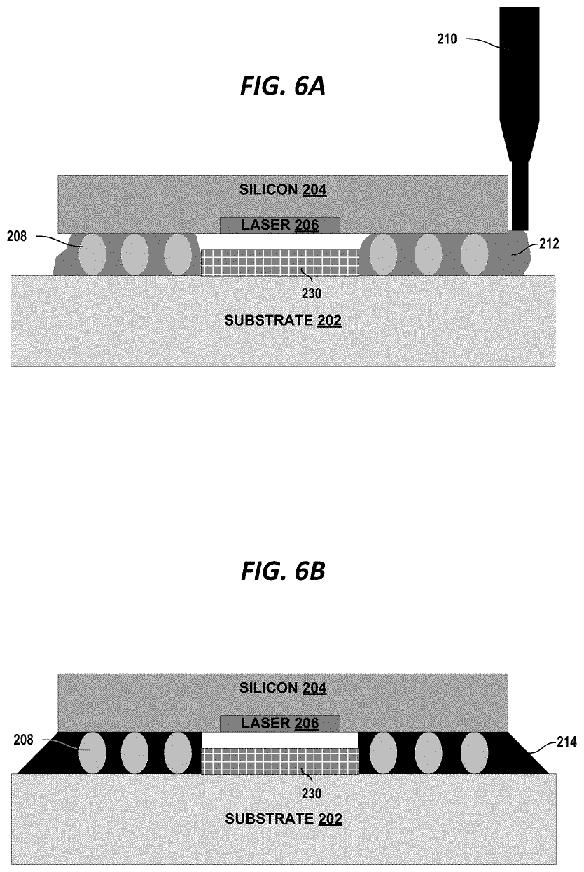

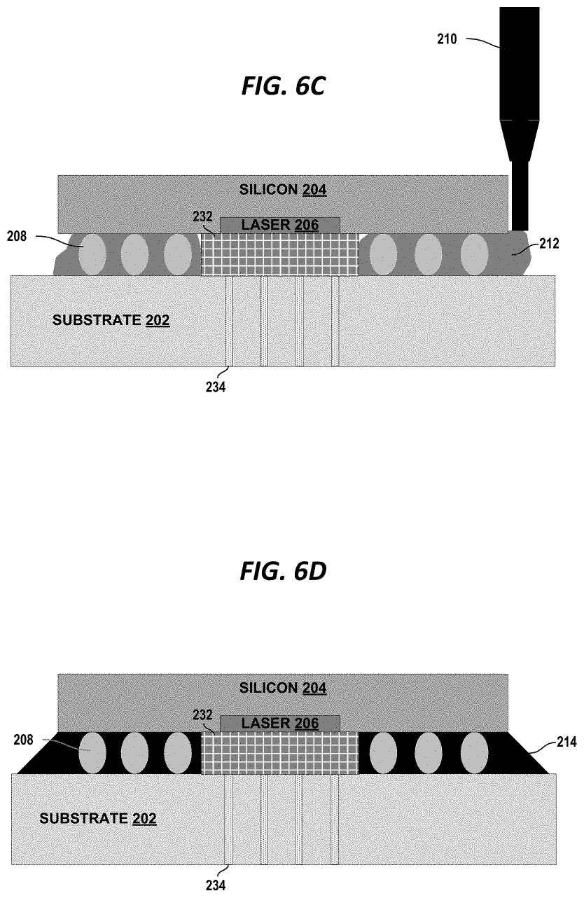

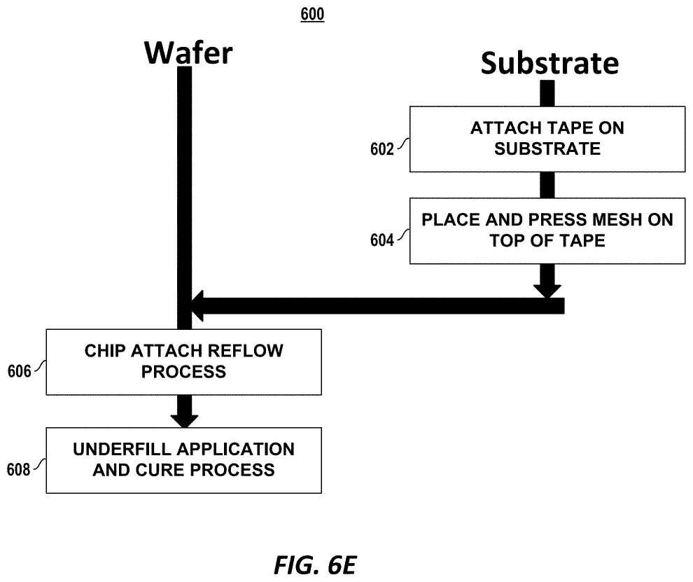

FIG. 6A-6E depict benzo cyclo butane (BCB) reinforced with nickel (Ni) meshes 230 and 232 and a corresponding flow 600 to protect a laser region 206 from underfill, in accordance with any of the embodiments disclosed herein. In various embodiments, other polymers with similar cross linked densities could be used along with any suitable (e.g., metal) mesh material.

During manufacturing of the meshes 230 or 232, Nickel oxide or other waste products may be removed from the BCB reinforced with nickel in a cleaning process using aqua regia buff. The reinforced BCB may then be singulated (e.g., by saw singulation) to form the mesh 230 or 232 of the appropriate size. The mesh 230 or 232 may then be attached to the substrate 202 using any suitable techniques, such as by tape (e.g., Kapton tape).

In one embodiment (e.g., as roughly depicted in FIG. 6A), the height of the mesh 230 is less than the chip gap (e.g., the distance from the bottom of silicon 204 to the top of substrate 202. For example, the height of the mesh 230 may be about 30 microns (e.g., when the chip gap between the bottom of the silicon 204 to the top of the substrate 202 is 40-45 microns). Accordingly, an air gap with a height of about 10-15 microns between the surface of laser region 206 and the mesh 230 will be present. Assuming that the dispense and curing process of underfill 212 is managed correctly, the underfill 212 will flow into the mesh but not into the air gap as the capillary force required for the flow to enter the mesh is lower than the capillary force required for the flow to enter the air gap (e.g., due to the high energy surface of the mesh). Other embodiments may include a mesh 230 with any suitable dimensions, with an air gap of any suitable height left between the top of the mesh 230 and the surface of the laser region 206. In various embodiments, the width of the mesh may be substantially equal too, less than, or greater than the width of the laser region 206.

In another embodiment (e.g., as roughly depicted in FIG. 6C), the mesh 232 may have a height that is substantially equal to the chip gap, such that the top of the mesh may contact (or rest very close to) the surface of the laser region 206. Assuming the underfill dispense process is correctly calibrated, the mesh attracts the underfill, but the underfill that enters the mesh does not rise to the level of the surface of the laser region 206 and thus the underfill does not contact the surface of the laser region 206. In at least some such embodiments, thru hole vias 234 may be formed below the mesh in the substrate 202 to alleviate any outgassing risks due to BCB degradation (the vias 234 may provide an escape path for the outgassing to prevent contact of the outgassing materials with the surface of laser region 206).

FIG. 6E depicts a flow for using a mesh to protect a surface of a laser region 206 from underfill 212 using a BCB reinforced with Ni mesh 230 or 232. At 602, tape is attached to a substrate (e.g., 202). Any suitable tap may be used, such as Kapton tape. The tape may include an adhesive material on both sides. At 604, the mesh 230 or 232 is placed on the tape and is pressed against the tape so as to adhere the mesh to the substrate.

At 606, an IC chip (e.g., comprising silicon 204 and laser region 206) is attached to the substrate 202 and the solder joints (e.g., 208) are reflowed to connect pads on the substrate to pads on the chip. At 608, underfill (e.g., 212) is applied to the space between the chip and the substrate and then the underfill is cured.

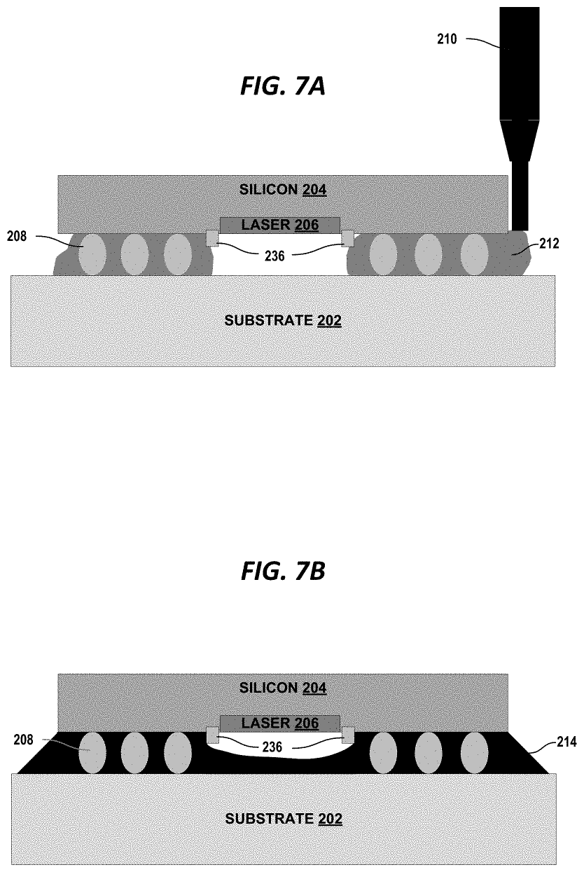

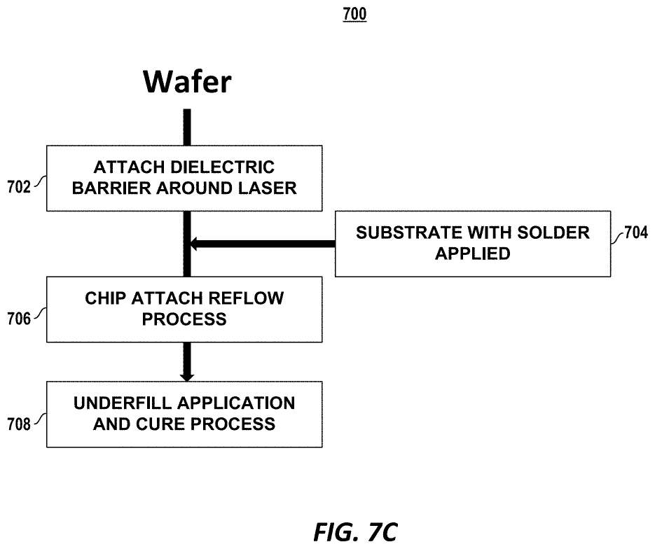

FIGS. 7A-7C depict a dielectric barrier 236 to protect a laser region 206 from underfill 212 and a flow 700 to use the dielectric barrier 236, in accordance with any of the embodiments disclosed herein. The dielectric barrier 236 may comprise any suitable dielectric material, such as polytetrafluoroethylene (PTFE). In various embodiments, the dielectric barrier 236 may include one or more materials with resistance to atmospheric or chemical degradation. The dielectric barrier 236 may be non-wettable, such that the underfill 212 is not allowed to penetrate the dielectric barrier 236.

The dielectric barrier 236 may be attached to the chip in any suitable manner. For example, the dielectric barrier 236 may be formed on the chip during the chip manufacturing process (e.g., through spinning, spraying, printing, deposition, or other suitable techniques). As another example, the dielectric barrier 236 may be manufactured separately from the chip and then fitted (e.g., into a trench formed in silicon 204 or other material around the laser region 206) onto the chip or otherwise attached to the chip around the laser region 206.

The dielectric barrier 236 may have any suitable geometry, such as an annular cylinder (e.g., similar to a washer or a gasket), a rectangular prism with a void in the middle, or other suitable geometry that may form a barrier around at least a portion of the laser region 206. The dielectric barrier 236 may completely surround the laser region 206 or may partially surround the laser region 206.

The dielectric barrier 236 may extend beyond the surface of the laser region 206 such that when the chip is flipped and placed on the substrate (as shown in FIG. 7A), the dielectric barrier 236 will block the flow of the underfill 212 and gravity will further retard the flow from flowing towards the surface of the laser region 206. The dispensed amount of the underfill 212 can be controlled to avoid the underfill from rising to the surface of the laser region 206. As shown in FIG. 7B, the cured underfill 214 is underneath the dielectric barrier 236 with a sufficient air gap between the top of the cured underfill 214 and the surface of the laser region 206.

FIG. 7C depicts a flow for utilizing a dielectric barrier 236 to protect a surface of a laser region 206. At 702, a dielectric barrier 236 is attached around the laser region 206. As just one example, the dielectric barrier 236 may be fitted into a trench having substantially the same shape as the dielectric barrier, wherein the trench is formed in the silicon 204 around the laser region 206. At 704, a substrate 202 with solder joints 208 applied is provided. At 706, the chip is attached to the substrate via a solder reflow process. At 708, underfill 212 is applied and cured.

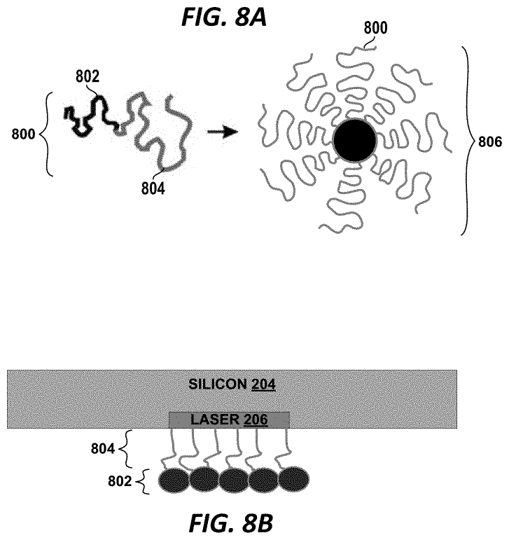

FIG. 8A depicts a di-block polymer 800, in which one portion 802 of the molecule is hydrophobic (insoluble) and one portion 804 of the molecule is hydrophilic (soluble). FIG. 8A also depicts a di-block polymer grouping 806, such as a micelle or vesicle, where the hydrophobic portions 802 of multiple molecules have organized in the middle of the grouping 806 and the hydrophilic portions 804 have organized towards the outside of the grouping 806.

FIG. 8B depicts an outermost surface of a block copolymer under dry conditions covered by a low surface energy component. In this embodiment, hydrophilic portions 804 of the molecules are positioned closer to the surface of the laser region 206 and hydrophobic portions 802 are positioned further from the laser region 206. Thus, when underfill 212 is applied, the hydrophobic portions 802 may repel the underfill away from the surface of the laser region 206.

As one example implementation of FIG. 8B, the surface of the laser region 206 may be coated with polydimethylsiloxane (PDMS) with hydrophobic terminals (e.g., 802). As a hydrophobic polymer, PDMS possesses characteristic properties including a high stability, low glass transition temperature (e.g., Tg=—123° C.), and low surface energy (e.g., 19.8 mN m−1). Epoxies (e.g., underfill 212) in general are hydrophilic (as they contain OH-groups), while PDMS includes various methyl groups and by nature is hydrophobic. Accordingly, these molecules generally migrate away from each other. Thus, the PDMS may be used to repel the underfill 212 away from laser region 206.

In various embodiments, PDMS segments may be incorporated into block copolymers (e.g., amphiphilic block copolymers coatings), with multifunctional characteristics and then placed on the surface of the laser region 206. The block copolymers can be tailored with hydrophilic terminals (e.g., 804) to self-assemble and form covalent bonds to the surface of the laser region 206 while the hydrophobic terminals (e.g., 802) can self-assemble to form a layer with low surface energy to face and repel the underfill 212, thus protecting the laser region 206 from contact with the underfill 212. In various embodiments, such copolymers may comprise PDMS as well as poly[oligo(ethylene glycol) methacrylate] (POEGMA).

Such copolymers may be applied to the laser surface in any suitable manner. For example, the wafer surface may be selectively coated in the laser regions 206 with the copolymer, through spin coating, spray coating, dipping or other suitable techniques. The IC chip may then be attached to the substrate as described herein.

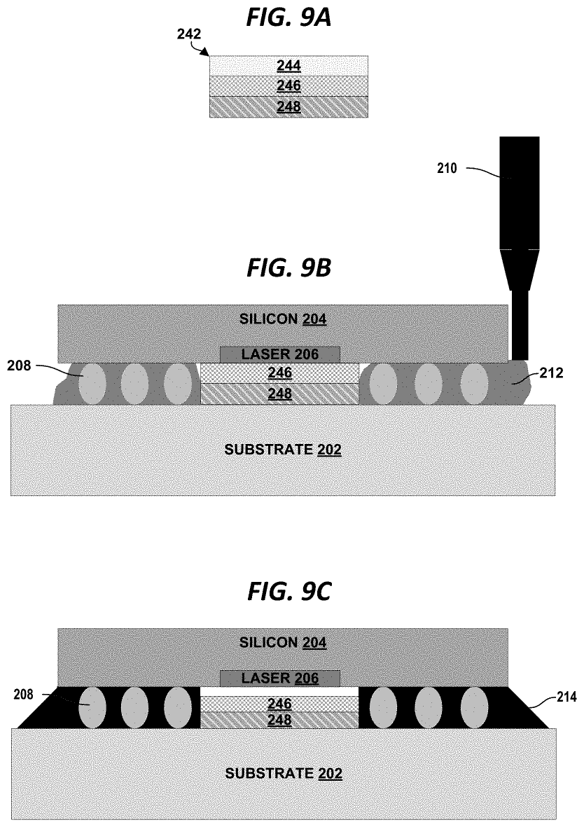

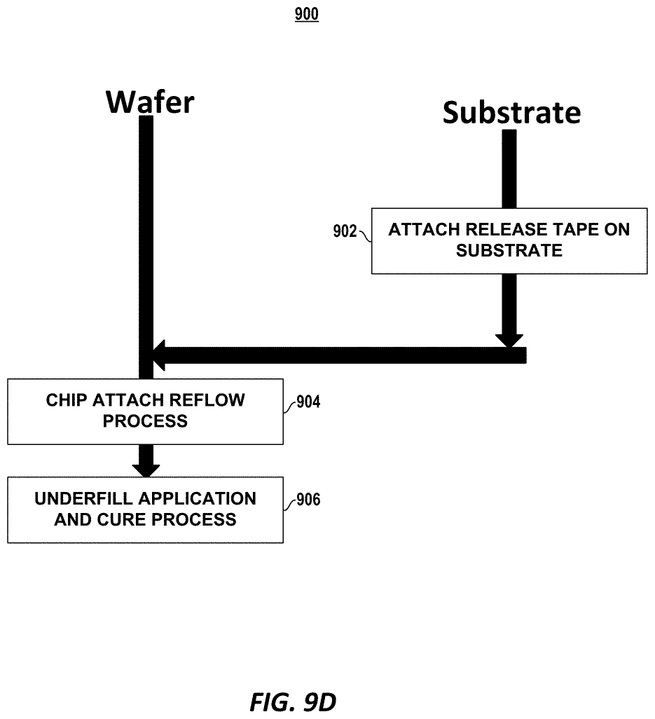

FIGS. 9A-9D depict release tape 242 and an associated flow 900 to protect a surface of a laser region 206 from underfill 212, in accordance with any of the embodiments disclosed herein. In the embodiment depicted, the release tape 242 comprises a release liner 244 to protect layer 246 during shipping and handling. The release liner 244 may be removed before the IC chip is aligned with the substrate during the connection process.

Layer 246 may comprise a thermal or ultraviolet (UV)-release material (e.g., polyimide or other suitable material) which may adhere to the surface of the laser region 206 during the dispensing of the underfill 212 to protect the surface of the laser region 206 from the underfill 212. In some embodiments, layer 246 may adhere to the laser region 206 upon initial attachment, but may release from the laser region 206 at a later time, e.g., responsive to a thermal condition (e.g., that may occur during curing of the underfill 212) or application of UV light. The release tape 242 may also comprise a backing layer 248 (e.g., an acrylic based polymer/adhesive) that may adhere to the substrate 202. The embodiment depicted is not necessarily drawn to scale (e.g., the thickness of each layer may vary). Similarly, additional layers may be present or one or more of the layers may not be present in other embodiments.

In various embodiments, as the underfill 212 cures, the release tape 242 will detach from the laser region 206, creating an air gap between the release tape 242 and the surface of the laser region 206. The release tape 242 may also morph during the curing process, resulting in a change of thickness of the release tape 242 (as shown in FIG. 9C).

FIG. 9D depicts a flow for utilizing the release tape 242 to protect the laser region 206. At 902, release tape 242 is attached on the substrate 202. In some embodiments, this may involve pressing the release tape 242 down with force onto the substrate 202 until adherence is achieved. This may also include removing a release liner 244 from the release tape. At 904, the chip is attached to the substrate using a solder reflow process. In some embodiments, when the chip is aligned with the substrate before the solder is melted, the laser region may also adhere to the other side of the release tape 242. At 906, underfill 212 is applied but does not contact the laser surface due to the placement of the release tape 242. The underfill 212 is also cured, which may result in release of the release tape 242 from the surface of the laser region 206.

FIG. 10 depicts a hydrophobic material 1000, according to any of the embodiments described herein. In the embodiment depicted, hydrophobic material 1000 includes a poly carbonate base 1002, short carbon chains 1004, and a hydrophobic surface 1006. In various embodiments, hydrophobic surface 1006 may be formed via a surface modification.

Various embodiments may include components (e.g., hydrophobic cylinders or other geometries, hydrophobic films, etc.) with hydrophobic material (e.g., 1000 or other hydrophobic material) that may have a repellant effect on underfill 212 and thus may retard the flow of underfill 212 during the dispensing process. The hydrophobic material may be formed on the IC chip or substrate 202 using any suitable techniques, such as spinning, spraying, printing, deposition, or other suitable techniques.

A hydrophobic material may include any suitable material with a repellant effect on the underfill 212. In various embodiments, the hydrophobic material may comprise a monolayer hydrophobic coating (e.g., that may be applied via spinning, spraying, or printing) such as a fluoro polymer, fluoro alkyl silane, dodecyl amine, dimethyl siloxane, hydrophobic fumed silica, or other suitable material. In some embodiments, the hydrophobic material may be formed by reacting dodecylamine with a surface to create a hydrophobic surface.

In some embodiments, the hydrophobic material may comprise one or more materials dissolved in one or more solvents such as bis[3-(trimethoxysilyl)propyl]aminosilane (ABPTMS) at room temperature. ABPTMS is an amine-terminated silane coupling reagent bearing secondary amine groups and can form strong urethane bonds by reacting with the carbonate groups of poly carbonate (PC) (without heat or surface oxidation in at least some embodiments). Any other suitable hydrophobic material may be used in the various embodiments described herein.

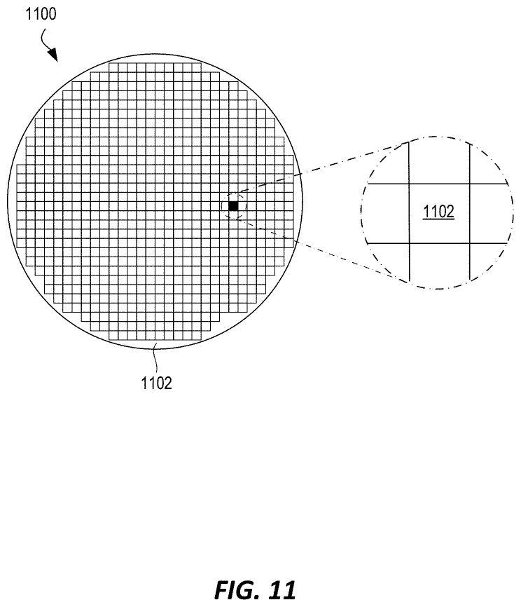

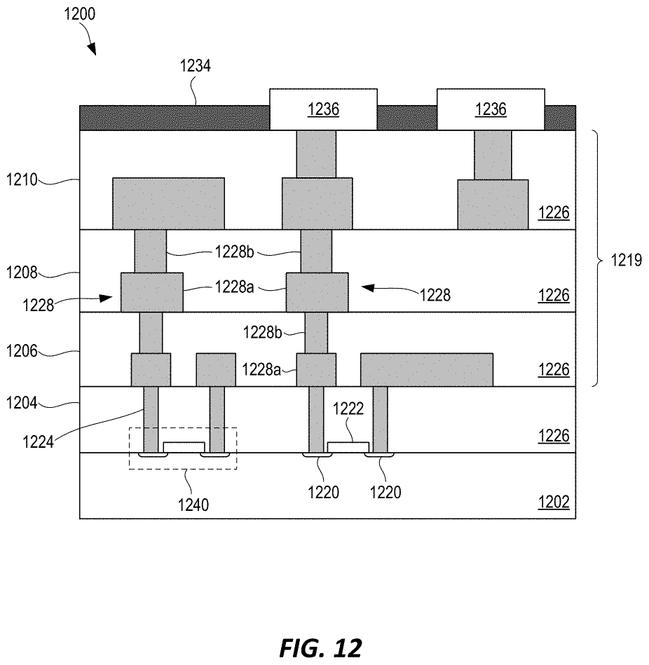

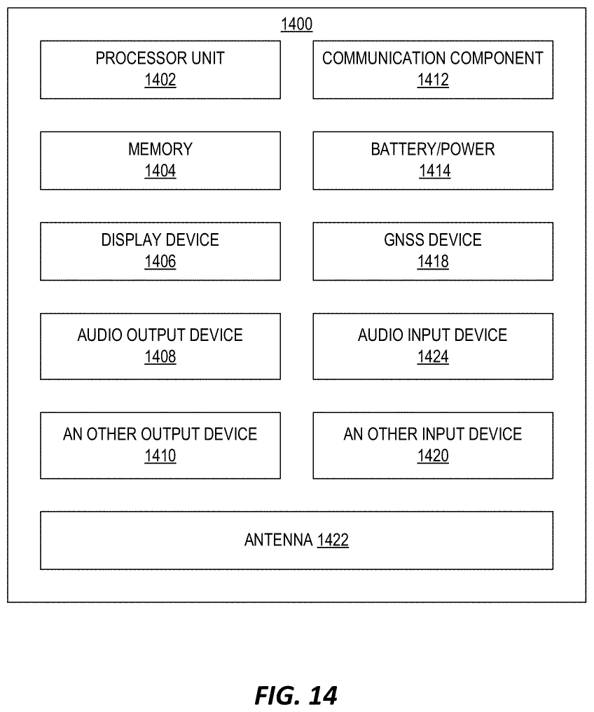

FIG. 11 is a top view of a wafer 1100 and dies 1102, where a die 1102 may be representative of an integrated circuit chip (e.g., TOSA 100) disclosed herein. The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may include one or more transistors (e.g., some of the transistors 1240 of FIG. 12, discussed below), supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1402 of FIG. 14) or other logic that is configured to store information in the memory devices or execute instructions stored in the memory array. Various ones of the integrated circuit chips disclosed herein may be manufactured using a die-to-wafer assembly technique in which some dies (e.g., a die comprising one or more lasers or other regions to be protected from underfill) are attached to a wafer 1100 that include other dies, and the wafer 1100 is subsequently singulated.

FIG. 12 is a cross-sectional side view of an integrated circuit device 1200 that may be included in any of the integrated circuit chips disclosed herein (e.g., in TOSA 100). One or more of the integrated circuit devices 1200 may be included in one or more dies 1102 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

The integrated circuit device 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page from the perspective of FIG. 11. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the lines 1228a of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (i.e., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices (e.g., substrate 202). For example, solder bonds may be formed on the one or more conductive contacts 1236 to mechanically and/or electrically couple an integrated circuit die including the integrated circuit device 1200 with another component (e.g., a printed circuit board). In one embodiment, conductive contacts 1236 may couple to conductive contacts of substrate 202 via solder joints 208. The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the circuit device 1200, and the metallization stack 1219 can be used to route I/O signals from the conductive contacts 1236 to transistors 1240 and any other components integrated into the circuit device 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder joints (microbumps).

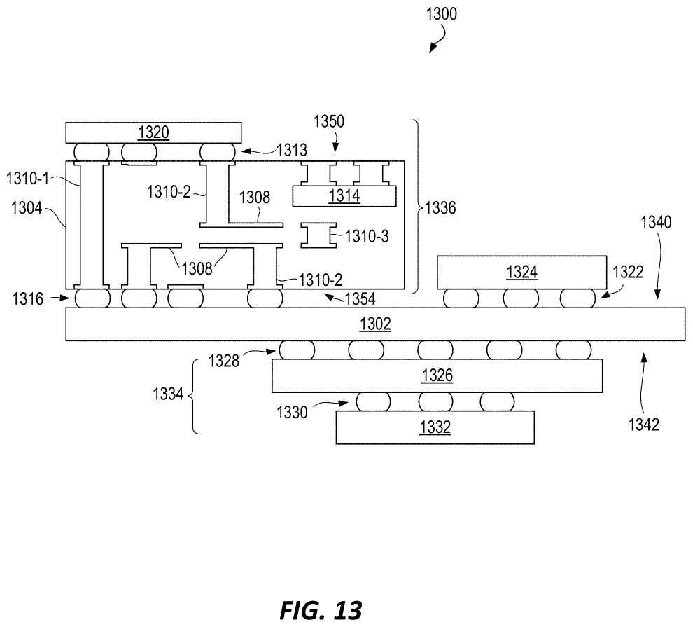

FIG. 13 is a cross-sectional side view of an integrated circuit device assembly 1300 that may include any of the integrated circuit chips disclosed herein. The integrated circuit device assembly 1300 includes a number of components disposed on a circuit board 1302 (which may be a motherboard, system board, mainboard, etc.). The integrated circuit device assembly 1300 includes components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. In one embodiment, substrate 202 may comprise circuit board 1302. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The integrated circuit device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1316 may serve as the coupling components illustrated or described for any of the substrate assembly or substrate assembly components described herein, as appropriate.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpacked integrated circuit product that includes one or more integrated circuit dies (e.g., the die 1102 of FIG. 11, the integrated circuit device 1200 of FIG. 12) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1320, a single monolithic integrated circuit die comprises solder joints attached to contacts on the die. The solder joints allow the die to be directly attached to the interposer 1304. The integrated circuit component 1320 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1320 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1320 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310-1 (that extend from a first face 1350 of the interposer 1304 to a second face 1354 of the interposer 1304), blind vias 1310-2 (that extend from the first or second faces 1350 or 1354 of the interposer 1304 to an internal metal layer), and buried vias 1310-3 (that connect internal metal layers).

In some embodiments, the interposer 1304 can comprise a silicon interposer. Through silicon vias (TSV) extending through the silicon interposer can connect connections on a first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art. In embodiments where the interposer is a non-printed circuit board

The integrated circuit device assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit device assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include one or more of the IC chips and substrates disclosed herein. For example, any suitable ones of the components of the electrical device 1400 may include one or more of the integrated circuit device assemblies 1300, integrated circuit components 1320, integrated circuit devices 1200, or integrated circuit dies 1102 disclosed herein. A number of components are illustrated in FIG. 14 as included in the electrical device 1400, but any one or more of these components may be omitted or duplicated, as suitable for the application. In some embodiments, some or all of the components included in the electrical device 1400 may be attached to one or more motherboards mainboards, or system boards. In some embodiments, one or more of these components are fabricated onto a single system-on-a-chip (SoC) die.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1424 or an audio output device 1408, but may include audio input or output device interface circuitry (e.g., connectors and supporting circuitry) to which an audio input device 1424 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1400 can comprise one or more processor units 1402 that are heterogeneous or asymmetric to another processor unit 1402 in the electrical device 1400. There can be a variety of differences between the processing units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1412 may operate in accordance with other wireless protocols in other embodiments. The electrical device 1400 may include an antenna 1422 to facilitate wireless communications and/or to receive other wireless communications (such as AM or FM radio transmissions).

In some embodiments, the communication component 1412 may manage wired communications, such as electrical, optical, or any other suitable communication protocols (e.g., IEEE 802.3 Ethernet standards). As noted above, the communication component 1412 may include multiple communication components. For instance, a first communication component 1412 may be dedicated to shorter-range wireless communications such as Wi-Fi or Bluetooth, and a second communication component 1412 may be dedicated to longer-range wireless communications such as global positioning system (GPS), EDGE, GPRS, CDMA, WiMAX, LTE, EV-DO, or others. In some embodiments, a first communication component 1412 may be dedicated to wireless communications, and a second communication component 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include an audio input device 1424 (or corresponding interface circuitry, as discussed above). The audio input device 1424 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1418 (or corresponding interface circuitry, as discussed above), such as a Global Positioning System (GPS) device. The GNSS device 1418 may be in communication with a satellite-based system and may determine a geolocation of the electrical device 1400 based on information received from one or more GNSS satellites, as known in the art.

The electrical device 1400 may include an other output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include an other input device 1420 (or corresponding interface circuitry, as discussed above). Examples of the other input device 1420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” may refer to layers or components that are in physical contact with each other. That is, there is no layer or component between the stated adjacent layers or components. For example, a layer X that is adjacent to a layer Y refers to a layer that is in physical contact with layer Y.

As used herein, “B is between A and C” may mean that at least part of B is in or along a space separating at least a part of A and at least a part of C and may mean that the at least part of B is in direct or indirect physical contact with A and/or C but could also include embodiments in which B is not in contact with any part of one or both of A or C.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein may mean that two or more elements are in direct physical contact, or that that two or more elements indirectly physically contact each other, but yet still cooperate or interact with each other (e.g., one or more other elements are coupled or connected between the elements that are said to be coupled with each other). The term “directly coupled” means that two or more elements are in direct contact.

As used herein, “A is proximate to B” may mean that A is adjacent to B or A is otherwise near to B.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc, as dictated by design needs or preferences, may actually comprise one or more signals that may travel in either direction and may be implemented with any suitable type of signal scheme.

The terms “substantially,” “close,” “approximately,” “near,” and “about,” may, in some embodiments, refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

Example 1 includes an apparatus comprising an integrated circuit chip comprising a first surface region and a second surface region adjacent to the first surface region; a substrate coupled to the integrated circuit chip through a plurality of connections comprising solder; and underfill between the substrate and the integrated circuit chip, wherein the underfill contacts the second surface region, but does not contact the first surface region.

Example 2 includes the subject matter of Example 1, and further comprising a material on the first surface region between the first surface region and the underfill.

Example 3 includes the subject matter of any of Examples 1 and 2, and wherein the material comprises a hydrophobic material.

Example 4 includes the subject matter of any of Examples 1-3, and wherein the material comprises silicon.

Example 5 includes the subject matter of any of Examples 1-4, and wherein the material comprises a block copolymer.

Example 6 includes the subject matter of any of Examples 1-5, and further including an air gap adjacent to the first surface region.

Example 7 includes the subject matter of any of Examples 1-6, and wherein the air gap is between the first surface region and a portion of the substrate facing the first surface region.

Example 8 includes the subject matter of any of Examples 1-7, and wherein the air gap is between the first surface region and underfill that is below the first surface region.

Example 9 includes the subject matter of any of Examples 1-8, and further including a plurality of hydrophobic structures on the substrate proximate to at least a portion of a perimeter of the first surface region.

Example 10 includes the subject matter of any of Examples 1-9, and further including a plurality of trenches on the substrate proximate to at least a portion of a perimeter of the first surface region.

Example 11 includes the subject matter of any of Examples 1-10, and further including a dielectric structure on the integrated circuit chip around at least a portion of the first surface region.

Example 12 includes the subject matter of any of Examples 1-11, and further including a metal reinforced polymer mesh on the substrate below the first surface region.

Example 13 includes the subject matter of any of Examples 1-12, and wherein the second surface region entirely surrounds the first surface region.

Example 14 includes the subject matter of any of Examples 1-13, and wherein the first surface region comprises a surface region of a laser of a transmitter optical sub-assembly.

Example 15 includes a system comprising an integrated circuit chip comprising a first surface region; a second surface region adjacent to the first surface region; and a material to prevent underfill from contacting the first surface region during an underfill dispensing operation in which underfill contacts at least a portion of the second surface region.

Example 16 includes the subject matter of Example 15, and further including a substrate coupled to the integrated circuit chip; and underfill between the substrate and the integrated circuit chip.

Example 17 includes the subject matter of any of Examples 15 and 16, and further including a processor unit to communicate with the integrated circuit chip, wherein the processor unit comprises at least one of a central processing unit (CPU), a graphics processor, a digital signal process, or a cryptographic processor.

Example 18 includes the subject matter of any of Examples 15-17, and further including a battery communicatively coupled to the processor unit, a display communicatively coupled to the processor unit, or a network interface communicatively coupled to the processor unit.

Example 19 includes the subject matter of any of Examples 15-18, and further including a material on the first surface region between the first surface region and the underfill.

Example 20 includes the subject matter of any of Examples 15-19, and wherein the material comprises a hydrophobic material.

Example 21 includes the subject matter of any of Examples 15-20, and wherein the material comprises silicon.

Example 22 includes the subject matter of any of Examples 15-21, and wherein the material comprises a block copolymer.

Example 23 includes the subject matter of any of Examples 15-22, and further including an air gap adjacent to the first surface region.

Example 24 includes the subject matter of any of Examples 15-23, and wherein the air gap is between the first surface region and a portion of the substrate facing the first surface region.

Example 25 includes the subject matter of any of Examples 15-24, and wherein the air gap is between the first surface region and underfill that is below the first surface region.

Example 26 includes the subject matter of any of Examples 15-25, and further including a plurality of hydrophobic structures on the substrate proximate to at least a portion of a perimeter of the first surface region.

Example 27 includes the subject matter of any of Examples 15-26, and further including a plurality of trenches on the substrate proximate to at least a portion of a perimeter of the first surface region.

Example 28 includes the subject matter of any of Examples 15-27, and further including a dielectric structure on the integrated circuit chip around at least a portion of the first surface region.

Example 29 includes the subject matter of any of Examples 15-28, and further including a polymer and a mesh on the substrate below the first surface region.

Example 30 includes the subject matter of any of Examples 15-29, and wherein the second surface region entirely surrounds the first surface region.

Example 31 includes the subject matter of any of Examples 15-30, and wherein the first surface region comprises a surface region of a laser of a transmitter optical sub-assembly.

Example 32 includes a method comprising aligning an integrated circuit chip with a substrate, the integrated circuit chip comprising a first surface region and a second surface region adjacent to the first surface region; melting a plurality of joints comprising solder to couple the integrated circuit chip to the substrate; and dispensing underfill between the integrated circuit chip and the substrate, the underfill contacting at least some of the plurality of joints, the substrate, and the second surface region, but not contacting the first surface region.

Example 33 includes the subject matter of Example 32, and further including coupling a material proximate the first surface region, the material to prevent the underfill from contacting the surface region.

Example 34 includes the subject matter of any of Examples 32 and 33, and further including forming a material on the first surface region between the first surface region and the underfill.

Example 35 includes the subject matter of any of Examples 32-34, and wherein the material comprises a hydrophobic material.

Example 36 includes the subject matter of any of Examples 32-35, and wherein the material comprises silicon.

Example 37 includes the subject matter of any of Examples 32-36, and wherein the material comprises a block copolymer.

Example 38 includes the subject matter of any of Examples 32-37, and further including forming an air gap adjacent to the first surface region.

Example 39 includes the subject matter of any of Examples 32-38, and wherein the air gap is between the first surface region and a portion of the substrate facing the first surface region.

Example 40 includes the subject matter of any of Examples 32-39, and wherein the air gap is between the first surface region and underfill that is below the first surface region.

Example 41 includes the subject matter of any of Examples 32-40, and further including forming a plurality of hydrophobic structures on the substrate proximate to at least a portion of a perimeter of the first surface region.

Example 42 includes the subject matter of any of Examples 32-41, and further including forming a plurality of trenches on the substrate proximate to at least a portion of a perimeter of the first surface region.

Example 43 includes the subject matter of any of Examples 32-42, and further including forming a dielectric structure on the integrated circuit chip around at least a portion of the first surface region.

Example 44 includes the subject matter of any of Examples 32-43, and further including forming a polymer and metal reinforced mesh on the substrate below the first surface region.

Example 45 includes the subject matter of any of Examples 32-44, and wherein the second surface region entirely surrounds the first surface region.

Example 46 includes the subject matter of any of Examples 32-45, and wherein the first surface region comprises a surface region of a laser of a transmitter optical sub-assembly.

1. An apparatus comprising:
an integrated circuit chip comprising a first surface region and a second surface region adjacent to the first surface region;
a substrate coupled to the integrated circuit chip through a plurality of connections comprising solder; and
underfill between the substrate and the integrated circuit chip, wherein the underfill contacts the second surface region, but does not contact the first surface region.

2. The apparatus of claim 1, further comprising a material on the first surface region between the first surface region and the underfill.

3. The apparatus of claim 2, wherein the material comprises a hydrophobic material.

4. The apparatus of claim 2, wherein the material comprises silicon.

5. The apparatus of claim 2, wherein the material comprises a block copolymer.

6. The apparatus of claim 1, further comprising an air gap adjacent to the first surface region.

7. The apparatus of claim 6, wherein the air gap is between the first surface region and a portion of the substrate facing the first surface region.

8. The apparatus of claim 6, wherein the air gap is between the first surface region and underfill that is below the first surface region.

9. The apparatus of claim 1, further comprising a plurality of hydrophobic structures on the substrate proximate to at least a portion of a perimeter of the first surface region.

10. The apparatus of claim 1, further comprising a plurality of trenches on the substrate proximate to at least a portion of a perimeter of the first surface region.

11. The apparatus of claim 1, further comprising a dielectric structure on the integrated circuit chip around at least a portion of the first surface region.

12. The apparatus of claim 1, further comprising a metal reinforced polymer mesh on the substrate below the first surface region.

13. The apparatus of claim 1, wherein the second surface region entirely surrounds the first surface region.

14. The apparatus of claim 1, wherein the first surface region comprises a surface region of a laser of a transmitter optical sub-assembly.

15. A system comprising:
an integrated circuit chip comprising:
a first surface region;
a second surface region adjacent to the first surface region; and
a material to prevent underfill from contacting the first surface region during an underfill dispensing operation in which underfill contacts at least a portion of the second surface region.

16. The system of claim 15, further comprising:
a substrate coupled to the integrated circuit chip; and
underfill between the substrate and the integrated circuit chip.

17. The system of claim 15, further comprising a processor unit to communicate with the integrated circuit chip, wherein the processor unit comprises at least one of a central processing unit (CPU), a graphics processor, a digital signal process, or a cryptographic processor.

18. The system of claim 17, further comprising a battery communicatively coupled to the processor unit, a display communicatively coupled to the processor unit, or a network interface communicatively coupled to the processor unit.

19. A method comprising:
aligning an integrated circuit chip with a substrate, the integrated circuit chip comprising a first surface region and a second surface region adjacent to the first surface region;
melting a plurality of joints comprising solder to couple the integrated circuit chip to the substrate; and
dispensing underfill between the integrated circuit chip and the substrate, the underfill contacting at least some of the plurality of joints, the substrate, and the second surface region, but not contacting the first surface region.

20. The method of claim 19, further comprising coupling a material proximate the first surface region, the material to prevent the underfill from contacting the surface region.
